(19) United States
(12) Patent Application Publication
(10) Pub. No.: US 2007/0171112 A1
(43) Pub. Date: Jul. 26, 2007

(54) Robust reference generation circuit for D/A converter

(76) Inventor: Sangbeom Park, Tracy, CA (US)

Correspondence Address: Kieun Park;DBA ANA Semiconductor, P.O. Box 65, Tracy, CA, 95376, US

(21) Appl. No.: 11/336,026

(22) Filed: Jan. 20, 2006

(51) Int. Cl. H03M 1/66

(52) U.S. Cl. 341/144

(57) ABSTRACT

Two reference generation circuits for D/A converter of the present invention generates a plurality of reference voltages characterized by voltage increments between two fixed reference voltages. These generated reference voltages greatly reduces unbalanced charge-injection errors that any fully differential architecture can not remove. The inaccuracy of D/A converters caused by the corrupted reference voltages is greatly minimized.

### FIELD OF THE INVENTION

The present invention relates to the field of digital-to-analog converters and more particularly to high-performance reference generation circuit for D/A converters basically utilizing a resistor string and two amplifiers.

### BACKGROUND ART

In interfacing between the digital and analog domain, the digital-to-analog (D/A) converter is a vitally important device. The D/A converter converts digital signals into an analog signal such as a voltage or current. For example, D/A converters are used in communications, appliances, video, computers, medical instrumentation, industries, and any other fields that require conversion of digital signals into analog forms. In most types of A/D converters, the D/A converter typically determines the accuracy and speed of A/D converters if the D/A converter is a subsection of A/D converters.

The D/A converter decodes digital input signals into an analog output signal. Most D/A converters basically include a resistor string which is comprised of a plurality of resistors. The resistors form a resistor string and are coupled in series between two potential voltages: the most positive potential voltage and the most negative potential voltage. In this resistor network, a set of reference voltages are generated at the nodes between the serially coupled resistors. These generated reference voltages are then connected to switches (or transmission gates) and pass the appropriate voltage to the output depending on the digital input word.

Prior Art FIG. 1 illustrates a circuit diagram of a conventional reference generation circuit for D/A converter 100. The conventional reference generation circuit for D/A converter shown in Prior Art FIG. 1 is comprised of a plurality of resistors, an amplifier 121, and a PMOS transistor 131. The resistors form a resistor string and are coupled in series between two potential voltages: the most positive reference voltages, V_{REFT}, and ground. It is noted that the positive input of the amplifier 121 is connected to the drain node of the PMOS transistor 131 and the output of the amplifier 121 is connected to the gate node of the PMOS transistor 131. In this configuration, the PMOS transistor 131 is used as an inverting gain stage rather than a source-follower stage. The gain of the PMOS transistor 131 depends on its device size, current, and the value of the resistor string. If an overall gain (i.e., a gain of amplifier 121 plus a gain of PMOS transistor 131) is sufficiently high, the positive input and negative input of the amplifier 121 are equal. In other words, the voltage at the node 101 becomes equal to V_{REFT} without regard to fluctuations of the power supply. This conventional reference generation circuit for D/A converter 100 generates a plurality of reference voltages characterized by voltage increments between the most positive reference voltages, V_{REFT}, and ground.

Unfortunately, the conventional reference generation circuit for D/A converter 100 is inefficient to implement in integrated circuit (IC) chip. First, the fact that the PMOS transistor 131 functions as an inverting gain stage with the feedback loop of the amplifier 121 makes the frequency compensation of the amplifier configuration more difficult under heavy load current in the CMOS technology. For instance, assuming the characteristics of the amplifier 121 and the device size of the PMOS transistor 131 are fixed, if the value of the resistor sting is reduced, then the load current flowing though the resistor string is increased. As a result, the phase margin of the open-loop at node 101 becomes worst. In addition to the difficulty of frequency compensation, it requires much more capacitance for the frequency compensation, which causes significant degradation in speed. Second, as the voltage at ground changes, the voltage at the node 104 will vary more than the voltage at the node 101. In other words, the power supply rejection with respect to ground rather than power supply is significantly degraded at the node 104. Third, in reality, switches are connected to the nodes between the serially coupled resistors in Prior Art FIG. 1. So, charge-injection errors occur at the nodes when the MOS switches turn off. The regulation at node 104 is much weaker than in the case of the node 101 during charge injection. Thus, the conventional reference generation circuit for D/A converter 100 is a major limitation on the high-resolution of D/A converter in integrated circuits (IC). In general, the main sources of error for most D/A converters are transistor charge-injection errors, inaccurate reference voltages, errors due to component mismatch, glitches, and settling-time errors. Basically, the reference voltages are basically coupled to switches (or transmission gates) in most D/A converters. In all cases, reference voltage path is from a node between the serially coupled resistors through a switch (or transmission gate) or multiple series switches. Even though all resistors are well matched in the resistor string with reasonable settling-time behavior, the reference voltages still suffer from charge-injection errors when the MOS switches turn off. Since the MOS switch transistors inject charges into their surrounding nodes when they are turned off, they give rise to charge-injection errors. Therefore, the charge-injection errors injected into the nodes between the serially coupled resistors will introduce a non-linearity into the reference block and, thus, corrupt the reference voltage accuracy significantly during charge injection. As a result, the correct analog output level is not guaranteed without reducing charge-injection errors for all types of D/A converters using resistor string. Especially, the charge injection is troublesome at high-speed D/A converters because a major limitation on the high-resolution of high-speed D/A converters is due to switch charge injection. There have been well known methods to reduce charge-injection errors in D/A converters are to use fully differential design techniques along with complementary references. But these conventionally well known methods are not effective. For instance, the fully differential architecture particularly removes only common-mode dc type of charge-injection errors but can not reduce distortion due to the unbalanced charge injection from switches. The reason why is because the charge-injection errors depend on input signal level, reference voltage level, the impedance at the source and drain of the switch, and so on. Therefore, the accuracy of D/A converters has been significantly degraded by the reference voltages distorted by the unbalanced charge injection from switches. The accuracy and high-resolution of D/A converters can not be achieved without the reference accuracy during charge injection for all types of D/A converters using resistor string.

Thus, what is needed is high performance reference generation circuits for D/A converter that can be easily designed and efficiently implemented along with minimizing unbalanced charge-injection errors and maximizing the power supply rejection with respect to both ground and power supply to achieve the high-resolution for all types of D/A converters using resistor string. The present invention satisfies these needs by providing two high performance reference generation circuits for D/A converter basically utilizing a resistor string and two amplifiers.

### SUMMARY OF THE INVENTION

The present invention provides two high-performance reference generation circuits for D/A converter. The high-performance reference generation circuits for D/A converter of the present invention basically includes a resistor string, a NMOS transistor, a PMOS transistor, two amplifiers (or operational amplifiers). The resistor string generates a plurality of reference voltages characterized by voltage increments between two fixed reference voltages. In this configuration, the two transistors are used as source-follower stages and each amplifier receives a reference voltage at its positive input. The generated reference voltages are not only constant with respect to the fluctuations of power supply and ground, but also greatly reduce unbalanced charge-injection errors. The present invention achieves a drastic improvement in charge-injection errors, power supply rejection, and design time for better time-to-market.

### BRIEF DESCRIPTION OF THE DRAWINGS

The accompanying drawings, which are incorporated in and form a part of this specification, illustrate embodiments of the invention and, together with the description, serve to explain the principles of the invention:

Prior Art FIG. 1 illustrates a circuit diagram of a conventional reference generation circuit for D/A converter.

FIG. 2 illustrates a circuit diagram of a robust reference generation circuit for D/A converter in accordance with the present invention.

FIG. 3 illustrates a circuit diagram of a dual-mode reference generation circuit for D/A converter according to the present invention.

### DESCRIPTION OF THE PREFERRED EMBODIMENTS

In the following detailed description of the present invention, two high-performance reference generation circuits for D/A converter, numerous specific details are set forth in order to provide a through understanding of the present invention. However, it will be obvious to one skilled in the art that the present invention may be practiced without these specific details. In other instances, well known methods, procedures, components, and circuits have not been described in detail so as not to unnecessarily obscure aspects of the present invention.

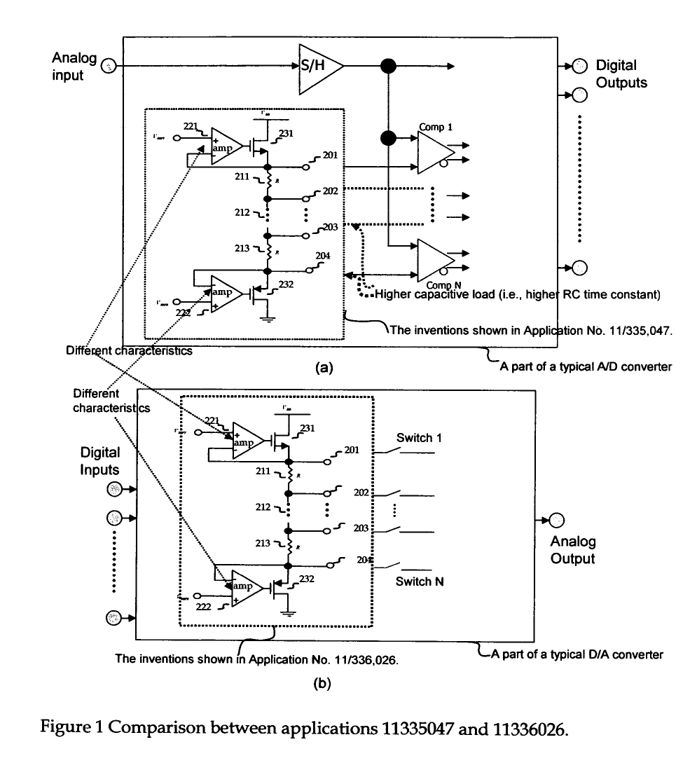

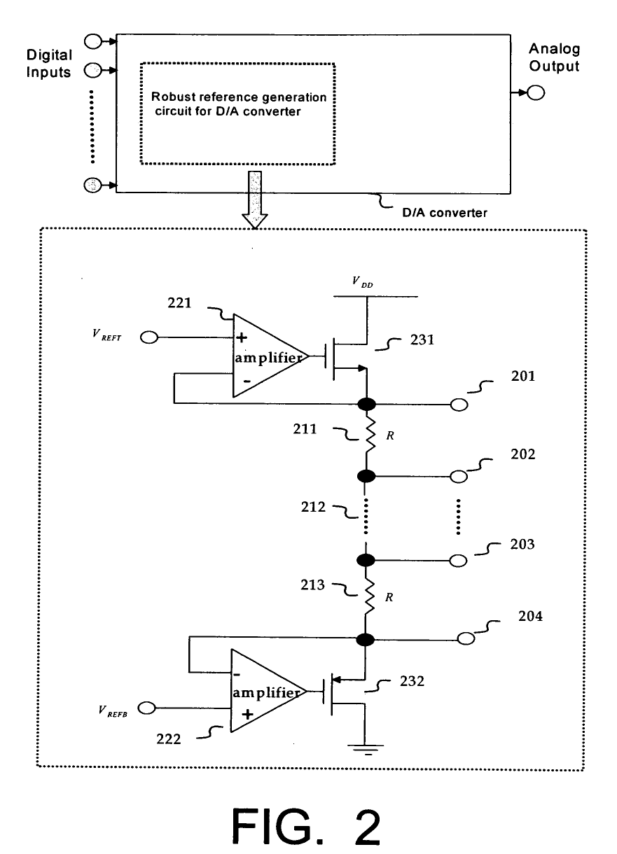

FIG. 2 illustrates a robust reference generation circuit for D/A converter in accordance with the present invention. The robust reference generation circuit for D/A converter 200 is comprised of n resistors, a NMOS transistor 231, a PMOS transistor 232, and two amplifiers (or operational amplifiers) 221 and 222. The resistor string generates n-1 evenly spaced reference voltages between two reference voltages such as V_{REFT} and V_{REFB}. The resistor string generates a plurality of reference voltages characterized by voltage increments between two fixed reference voltages. In this configuration, the two transistors are used as source-follower stages and each amplifier (or operational amplifier) receives a reference voltage at its positive input. It is noted that the negative input of the amplifier 221 is connected to the source node of the NMOS transistor 231 and its output is connected to the gate node of the NMOS transistor 231. Likewise, the negative input of the amplifier 222 is connected to the source node of the PMOS transistor 232 and its output is connected to the gate node of the PMOS transistor 232. If a gain of the amplifiers 221 and 222 is sufficiently high, then their positive input and negative input are equal. In other words, the voltage at the node 201 becomes equal to V_{REFT} and the voltage at the node 204 becomes equal to V_{REFB} without regard to fluctuations of the power supply and ground. First, since the NMOS and PMOS transistors are used as source-follower stages, the frequency compensation of the amplifiers (or operational amplifiers) 221 and 222 becomes easier even under heavy load current in the CMOS technology and, thus, greatly saves design time. Therefore, significant degradation in speed due to additional capacitance for the frequency compensation is avoided. Second, as the voltage at both power supply and ground changes, the voltage at the node 204 will be much more constant than the case of Prior Art FIG. 1. In other words, the power supply rejection with respect to ground and power supply becomes robust at the nodes 201 through 204 because the amplifier (or operational amplifier) 222 and PMOS transistor 232 are additionally utilized in the same fashion as the amplifier 221 and NMOS transistor 231. Third, a main source of error for all D/A converters using resistor string is the charge injection that occurs at the nodes between the serially coupled resistors. However, the regulation at the nodes 201 through 204 shown in FIG. 2 is much stronger than in the case of Prior Art FIG. 1 when charge injection occurs. Thus, the robust reference generation circuit for D/A converter 200 provides the strong basis for all high-resolution D/A converters using resistor string. In other words, the present invention greatly minimizes the inaccuracy of D/A converters caused by the corrupted reference voltages during charge injection. In addition, the present invention is not only cost-effective, but also yields a great reduction in design time for better time-to-market. The robust reference generation circuit for D/A converter 200 can be easily designed and efficiently implemented along with minimizing unbalanced charge-injection errors and maximizing the power supply rejection with respect to both ground and power supply to achieve the high-resolution for all types of D/A converters using resistor string. The present invention generates robust reference voltages utilizing a resistor string, two amplifiers (or operational amplifiers), and two transistors. Amplifiers are well known circuits in the art and can be implemented using various well known devices such as transistors, capacitors, resistors, etc. In addition, the amplifiers (or operational amplifiers) 221 and 222 are differential-input single-ended output amplifiers and can have any number of gain stages with or without buffer stage (i.e., output stage).

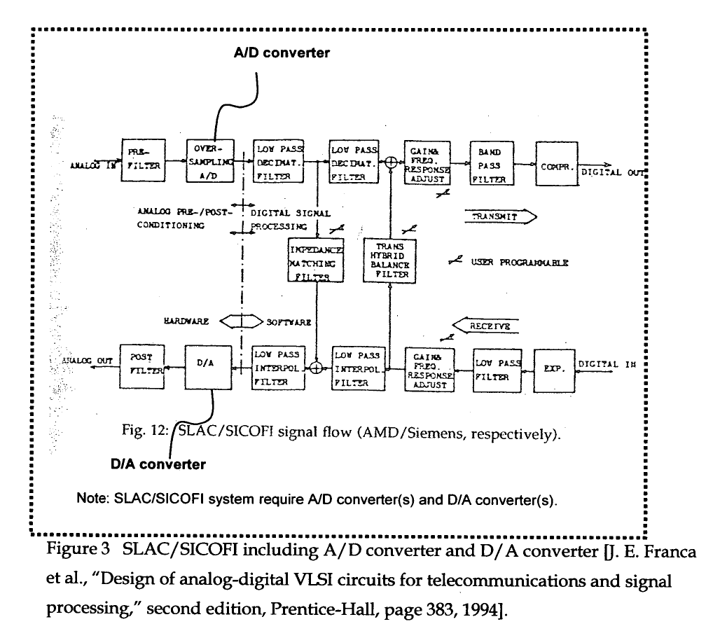

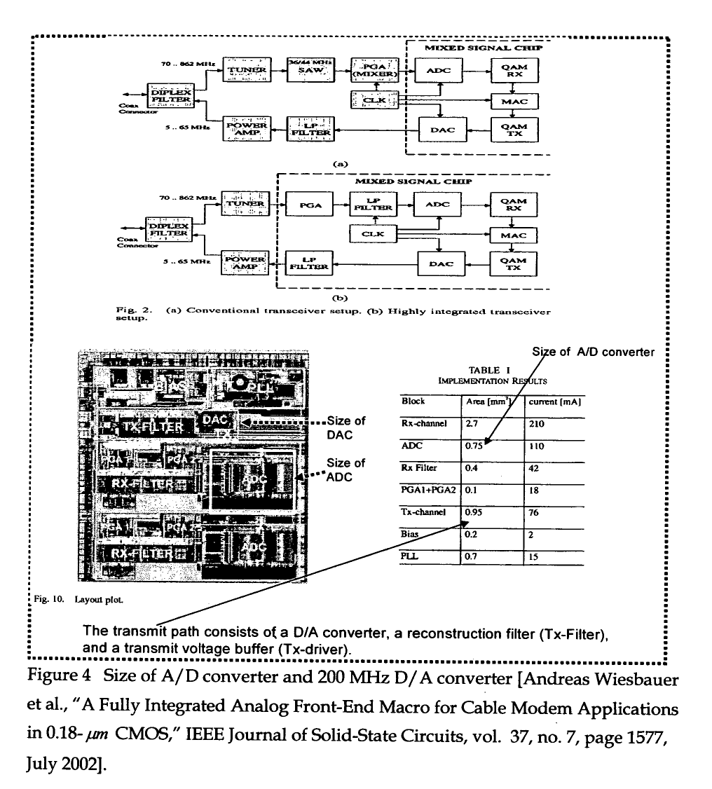

FIG. 3 illustrates a circuit diagram of a dual-mode reference generation circuit for D/A converter 300 according to the present invention. The dual-mode reference generation circuit for D/A converter 300 is comprised of n resistors, a NMOS transistor 331, a PMOS transistor 332, two amplifiers (or operational amplifiers) 321 and 322, and two switches 351 and 352. Switches are well known devices in the art and can be implemented using transistors.

Compared to FIG. 2, the first difference to note in the dual-mode reference generation circuit for D/A converter 300 is that two switches 351 and 352 are simply added to be connected between the negative input and the output of the amplifiers into FIG. 3. In addition, it is also noted that the amplifier configurations shown in FIG. 3 become unity-gain configurations when the switches 351 and 352 turn on and FIG. 3 becomes the same circuit as FIG. 2 when the switches 351 and 352 turn off. Thus, the dual-mode reference generation circuit for D/A converter 300 provides two types of robust reference generations: robust reference generation mode and robust reference generation mode using unity-gain amplifiers, which enable one D/A converter to function as two different D/A converters (i.e., two-in-one). One D/A converter is used for an application that requires high power supply rejection at the lower frequency and the other is for one that requires very low charge-injection errors. As a result, the dual-mode reference generation circuit for D/A converter 300 of the invention not only greatly saves cost but also widens the range of applications by simply adding only two switches. Since the position of a product in the market place evolves from its wide range of applications, the dual-mode reference generation circuit for D/A converter 300 of the present invention makes its position in the market much higher.

In summary, the robust reference generation circuit for D/A converter 200 and the dual-mode reference generation circuit for D/A converter 300 can also be implemented using additional capacitors attached to the nodes 201 through 204 and the nodes 301 through 304, respectively. In addition, the two reference generation circuits of the present invention are highly efficient to implement in integrated circuit (IC) and system-on-chip (SOC). The robust reference generation circuit for D/A converter 200 of the present invention achieves a drastic improvement in charge-injection errors, power supply rejection, and design time for better time-to-market. In addition to the strengths mentioned above, the dual-mode reference generation circuit for D/A converter 300 of the present invention provides wide range of applications along with much higher market positioning by utilizing both the robust reference generation and the robust reference generation using unity-gain amplifiers. While the present invention has been described in particular embodiments, it should be appreciated that the present invention should not be construed as being limited by such embodiments, but rather construed according to the claims below.

What is claimed is:

1. A reference generation circuit for D/A converter for generating reference voltages for D/A conversion, comprising:
a resistor string for generating a plurality of reference voltages wherein the n resistors are coupled in series between the two fixed reference voltages;
two MOS transistors for functioning as source-follower stages wherein the NMOS transistor is coupled to the most positive node of the resistor string and the PMOS transistor is coupled to the most negative node of the resistor string; and
two amplifiers for making the positive input and negative input equal wherein each positive input receives a reference voltage and each negative input is coupled to the source of each NOS transistor.

2. The circuit as recited in claim 1 wherein each of the n-1 reference voltages is generated at a node between the serially coupled resistors where n is an integer.

3. The circuit as recited in claim 1 wherein the amplifiers are amplifiers.

4. The circuit as recited in claim 1 wherein the amplifiers are operational amplifiers.

5. The circuit as recited in claim 1 wherein the amplifiers are differential-input single-ended output amplifiers.

6. The circuit as recited in claim 1 wherein the amplifiers are amplifiers with reasonable gain which equalizes the positive input and negative input.

7. The circuit as recited in claim 1 further comprising capacitors coupled to the nodes between the serially coupled resistors.

8. The circuit as recited in claim 1 wherein the reference generation circuit is applied to all types of D/A converters using resistor string.

9. A reference generation circuit for D/A converter for generating reference voltages for D/A conversion, comprising:
a resistor string for generating a plurality of reference voltages wherein the n resistors are coupled in series between the two fixed reference voltages;
two MOS transistors for functioning as source-follower stages wherein the NMOS transistor is coupled to the most positive node of the resistor string and the PMOS transistor is coupled to the most negative node of the resistor string;
two amplifiers for making the positive input and negative input equal wherein each positive input receives a reference voltage and each negative input is coupled to the source of each NOS transistor; and
two switches for making dual modes wherein each switch is coupled between the negative input and the output of each amplifier.

10. The circuit as recited in claim 9 wherein each of the n-1 reference voltages is generated at a node defined by the junctions between the serially coupled resistor components where n is an integer.

11. The circuit as recited in claim 9 wherein the amplifiers are amplifiers.

12. The circuit as recited in claim 9 wherein the amplifiers are operational amplifiers.

13. The circuit as recited in claim 9 wherein the amplifiers are differential-input single-ended output amplifiers.

14. The circuit as recited in claim 9 wherein the amplifiers are amplifiers with reasonable gain which equalizes the positive input and negative input.

15. The circuit as recited in claim 9 further comprising capacitors coupled to the nodes between the serially coupled resistors.

16. The circuit as recited in claim 9 wherein the reference generation circuit is applied to all types of D/A converters using resistor string.

17. The circuit as recited in claim 9 wherein the switches are NMOS transistors.

18. The circuit as recited in claim 9 wherein the switches are PMOS transistors.

19. The circuit as recited in claim 9 wherein the switches are CMOS transistors.

20. The circuit as recited in claim 9 wherein the switches are a PMOS transistor and a NMOS transistor.
